(19) United States
(12) Patent Application Publication
(10) Pub. No.: US 2015/0103282 A1
(43) Pub. Date: Apr. 16, 2015

(54) LIQUID CRYSTAL DISPLAY AND MANUFACTURING METHOD THEREOF

(71) Applicant: Samsung Display Co., Ltd., Yongin-City (KR)

(72) Inventors: Je Hyeong PARK, Hwaseong-si (KR); Kyung Seop KIM, Hwaseong-si (KR); Hyung June KIM, Anyang-si (KR); Tae Kyung YIM, Seoul (KR); Ki Pyo HONG, Hwaseong-si (KR)

(21) Appl. No.: 14/445,839

(22) Filed: Jul. 29, 2014

(30) Foreign Application Priority Data
Oct. 14, 2013 (KR) 10-2013-0122085

(51) Int. Cl. G02F 1/1362; G02F 1/1341; G02F 1/1343; H01L 27/12; G02F 1/1368

(52) U.S. Cl. CPC G02F 1/136209; H01L 27/1259; G02F 1/1368; G02F 1/136277; G02F 1/13439; G02F 1/1341
USPC 349/44; 438/30

(57) ABSTRACT

A liquid crystal display device includes: a substrate; a thin film transistor (TFT) having a semiconductive layer formed on the substrate and source and drain electrodes formed on the semiconductive layer; an interlayer insulating layer formed on the thin film transistor and formed with a contact hole partially exposing the drain electrode; a first light blocking structure-forming layer covering the contact hole and connected to the drain electrode; a second light blocking structure-forming layer formed on the first light blocking structure-forming layer; a pixel electrode formed on the interlayer insulating layer; and a common electrode disposed to face the pixel electrode, wherein at least one microcavity having a respective liquid crystal injection hole is formed between the pixel electrode and the common electrode, and the microcavity is filled to contain therein a liquid crystal layer portion formed of liquid crystal molecules. The first and second light blocking structure-forming layers allow for repair of the TFT while providing to the TFT protection from leakage light. A material of the second light blocking structure-forming layer is selected to include one that is not damaged by a process step of selectively removing a sacrificial layer.

### CROSS-REFERENCE TO RELATED APPLICATION

This application claims priority to and the benefit of Korean Patent Application No. 10-2013-0122085 filed in the Korean Intellectual Property Office on Oct. 14, 2013, the entire contents of which application are incorporated herein by reference.

### BACKGROUND

(a) Field

The present disclosure of invention relates to a liquid crystal display and a manufacturing method thereof.

(b) Description of Related Technology

Liquid crystal displays (LCD's) are currently one of the most widely used type of flat or otherwise thin panel displays. The typical LCD includes two spaced apart display panels having formed thereon electric field generating electrodes such as a pixel electrode and an opposed common electrode. A liquid crystal layer is interposed between the two display panels and adjacent to the opposed electrodes such that an electric field can be generated and passed through the liquid crystal layer.

The liquid crystal display (LCD) forms its to be displayed images by generating appropriate electric fields through the liquid crystal layer for example by applying corresponding voltages across the opposed field generating electrodes. The generated electric fields determine respective alignments of liquid crystal molecules within the liquid crystal layer and such alignments are used for controlling polarization of incident light.

An NCD (nanocrystal display) refers herein to a device that is made by forming a selectively sacrificable layer composed of an organic material, forming a roof layer on an upper part thereof, selectively removing the sacrificable layer to thereby form a microcavity, and then filling the microcavity formed by the removal of the sacrificial layer with a liquid crystal.

In a manufacturing process of the NCD type liquid crystal display, repair of thin film transistors (TFT) included therein may entail forming an opening through a light blocking member in a region corresponding to where the thin film transistor is formed.

In this instance, in order to prevent light leakage in the thin film transistor formation region where the light blocking member is exposed for purposes of repair, it might be desirable to form an additional light blocking structure-forming layer after forming a corresponding pixel electrode.

However, one or both of the first and second light blocking structure-forming layers as described above might be damaged in subsequent processes such as when ashing is used for forming the microcavity.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding invention dates of subject matter disclosed herein.

### SUMMARY

The present disclosure of invention provides a liquid crystal display including a light blocking structure-forming layer and a method for manufacturing the same which is not damaged by a subsequent process for forming a microcavity.

An exemplary embodiment of the present invention provides a liquid crystal display including: a substrate; a thin film transistor including a semiconductive layer formed on the substrate and source and drain electrodes formed on the semiconductive layer; an interlayer insulating layer formed on the thin film transistor and formed with a contact hole partially exposing the drain electrode; a first light blocking structure-forming layer covering the contact hole and connected to the drain electrode; a second light blocking structure-forming layer formed on the first light blocking structure-forming layer; a pixel electrode formed on the interlayer insulating layer; and a common electrode disposed to face the pixel electrode, wherein a microcavity having a liquid crystal injection hole is formed between the pixel electrode and the common electrode, and the microcavity includes a liquid crystal layer formed of liquid crystal molecules.

In this instance, the first light blocking structure-forming layer may contact the drain electrode.

The second light blocking structure-forming layer may overlap the first light blocking structure-forming layer.

The first light blocking structure-forming layer may be connected to the pixel electrode.

The first light blocking structure-forming layer may be integrally formed with the pixel electrode.

The drain electrode may contain copper (Cu).

The first light blocking structure-forming layer may contain indium tin oxide (ITO) or indium zinc oxide (IZO).

The second light blocking structure-forming layer may contain titanium (TI).

A light blocking member disposed between the thin film transistor and the interlayer insulating layer is further included, and the light blocking member may be formed with an opening corresponding to the contact hole exposing the drain electrode.

In this instance, a lower insulating layer disposed on the common electrode may be further included. A roof layer disposed on the lower insulating layer may be further included.

A capping layer disposed on the roof layer covering the liquid crystal injection hole may be further included.

In this instance, the microcavity includes a plurality of regions corresponding to pixel regions, the liquid crystal injection hole formation region is formed between the plurality of regions, and the capping layer may cover the liquid crystal injection holes forming region.

The liquid crystal injection holes forming region may be formed in a direction parallel with a gate line connected to the thin film transistor.

A third light blocking structure-forming layer disposed under the first light blocking structure-forming layer contacting the drain electrode may be further included.

The pixel electrode may be connected to the second light blocking structure-forming layer.

The pixel electrode may partially overlap the second light blocking structure-forming layer.

The first to third light blocking structure-forming layers may overlap each other.

The drain electrode may be a triple layer sequentially laminated with molybdenum (Mo), aluminum (Al), and molybdenum (Mo).

The third light blocking structure-forming layer may contain copper.

A manufacturing method of the liquid crystal display according to an exemplary embodiment of present disclosure includes: forming a thin film transistor on a substrate; forming an interlayer insulating layer on the thin film transistor; forming a contact hole at the interlayer insulating layer to expose a drain electrode of the thin film transistor; forming a pixel electrode layer on the interlayer insulating layer; forming a first light blocking structure-forming layer and a pixel electrode by patterning the pixel electrode layer; forming a second light blocking structure-forming layer on the first light blocking structure-forming layer; forming a sacrificial layer on the second light blocking structure-forming layer and the pixel electrode; forming a common electrode on the sacrificial layer; forming a roof layer on the common layer; forming a liquid crystal injection holes forming region by patterning the common electrode and the roof layer; and forming a microcavity in which a liquid crystal injection hole is formed by removing the sacrificial layer.

In this instance, the first light blocking structure-forming layer may be formed to contact the drain electrode while covering the contact hole.

The first light blocking structure-forming layer may be integrally formed with the pixel electrode.

Forming a light blocking member disposed between the thin film transistor and the interlayer insulation member is further included, and the light blocking member may be formed to have an opening corresponding to the contact hole exposing the drain electrode.

A manufacturing method of the liquid crystal display according to an exemplary embodiment includes: forming a thin film transistor on a substrate; forming an interlayer insulating layer on the thin film transistor; forming a contact hole at the interlayer insulating layer to expose a drain electrode of the thin film transistor; forming a third light blocking structure-forming layer on the interlayer insulating layer to cover the contact hole; forming a first light blocking structure-forming layer which is formed on the third light blocking structure-forming layer to be overlapped therewith; forming a second light blocking structure-forming layer which is formed on the first light blocking structure-forming layer to be overlapped therewith; forming a pixel electrode on the interlayer insulating layer; forming a sacrificial layer on the second light blocking structure-forming layer and the pixel electrode; forming a common electrode on the sacrificial layer; forming a roof layer on the common electrode; forming a liquid crystal injection holes forming region by patterning the common electrode and the roof layer; and forming a microcavity in which the liquid crystal injection hole is formed by removing the sacrificial layer.

In this instance, forming a pixel electrode on the interlayer insulating layer includes forming a pixel electrode layer on the interlayer insulating layer and the second light blocking structure-forming layer, and forming the pixel electrode by patterning the pixel electrode layer.

The pixel electrode may be formed to partially overlap the second light blocking structure-forming layer.

The pixel electrode may be connected to the second light blocking structure-forming layer.

Forming a light blocking member disposed between the thin film transistor and the interlayer insulating layer may be further included, and the light blocking member may be formed to have an opening corresponding to the contact hole exposing the drain electrode.

According to an exemplary embodiment of the present disclosure of invention, by having the plurality of light blocking structure-forming layers to cover the thin film transistor forming region where the light blocking member is exposed, wherein at least the second light blocking structure-forming layer is not damaged in a process such as ashing to form a microcavity.

### BRIEF DESCRIPTION OF THE DRAWINGS

FIG. 1 is a top plan view of a liquid crystal display according to an exemplary embodiment.

FIG. 2 is a cross-sectional view of FIG. 1, taken along the line II-II.

FIG. 3 is a cross-sectional view of FIG. 1, taken along the line III-III.

FIGS. 4 to 12 are drawings sequentially showing a manufacturing method of a liquid crystal display according to the exemplary embodiment.

FIG. 13 is a top plan view of a liquid crystal display according to another exemplary embodiment.

FIG. 14 is a cross-sectional view of FIG. 13, taken along the line XIV-XIV.

FIGS. 15 to 17 are drawings sequentially showing a manufacturing method of a liquid crystal display according to another exemplary embodiment.

### DETAILED DESCRIPTION

The present disclosure of invention will be described more fully hereinafter with reference to the accompanying drawings, in which exemplary embodiments in accordance with the disclosure are shown.

As those skilled in the art would realize in light of this disclosure, the described embodiments may be modified in various different ways, all without departing from the spirit or scope of the present teachings.

On the contrary, exemplary embodiments introduced herein are provided to make the disclosure thorough and complete and sufficient for transferring the spirit of the present disclosure of invention to those skilled in the pertinent art.

In the drawings, the thickness of layers and regions may be exaggerated for clarity.

In addition, when a layer is described to be formed on another layer or on a substrate, this means that the layer may be formed on the other layer or on the substrate, or a third layer may be interposed between the layer and the other layer or the substrate. Like reference numerals designate like elements throughout the specification.

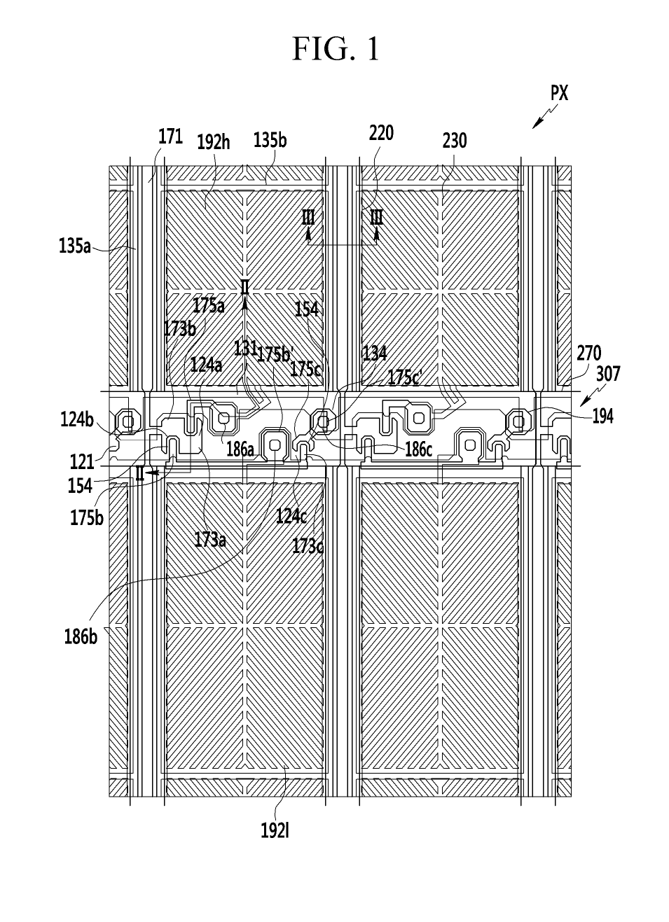

FIG. 1 is a top plan view of a liquid crystal display according to an exemplary embodiment.

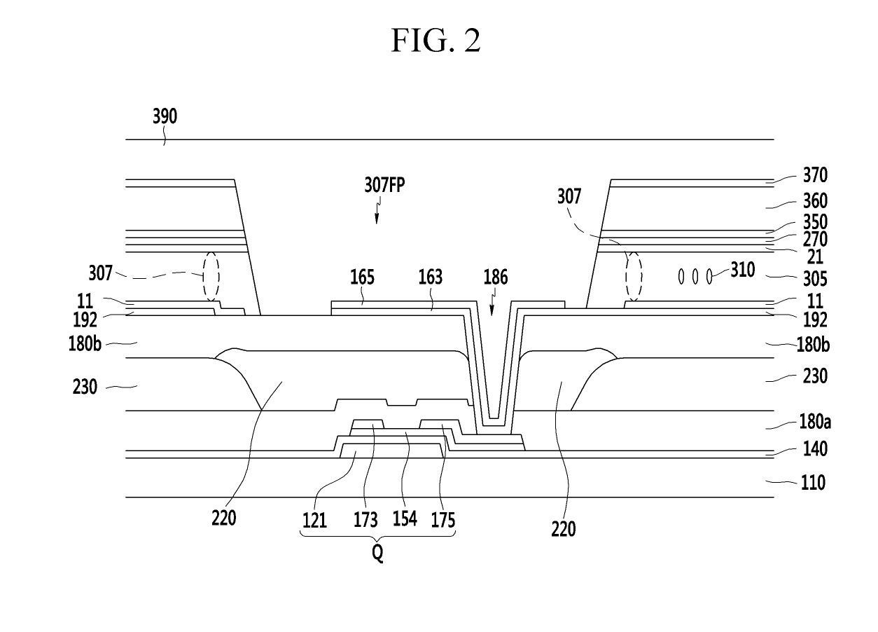

FIG. 2 is a cross-sectional view of FIG. 1, taken along the line II-II.

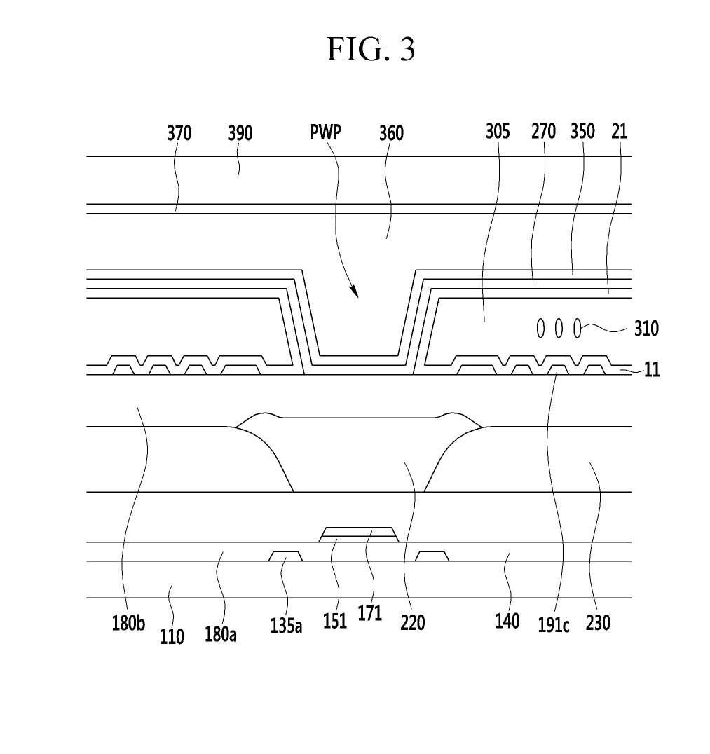

FIG. 3 is a cross-sectional view of FIG. 1, taken along the line III-III.

Referring to FIG. 1 to FIG. 3, the liquid crystal display (LCD) device according to the exemplary embodiment, has a plurality of light blocking structure-forming layers which are configured so as not to be damaged for example by an ashing process used forming microcavities in the display device. The LCD device includes a substrate 110, a thin film transistor Q, interlayer insulating layers 180a and 180b, first and second light blocking structure-forming layers or members 163 and 165, a pixel electrode 192, a common electrode 270, a lower insulating layer 350, and a roof layer 360.

A gate line 121 and a storage voltage line 131 are formed on the insulating substrate 110 made for example of a transparent glass or light-passing plastic.

The gate line 121 includes a first gate electrode 124a, a second gate electrode 124b, and a third gate electrode 124c all integrally branching from the gate line 121.

The storage voltage line 131 includes storage electrodes 135a and 135b, and a protruding portion 134 which protrudes in a direction of the gate line 121.

The storage electrodes 135a and 135b have a structure surrounding a first sub-pixel electrode 192h and a second sub-pixel electrode 192l of a previous pixel.

A horizontal portion of the storage electrode 135b may be a wire which is not separated from a horizontal portion of a previous pixel.

A gate insulating layer 140 is formed on the gate line 121 and the storage voltage line 131.

A first semiconductive member 151 is positioned below a data line 171, a second semiconductive member 155 is positioned below source and drain electrodes, and a third semiconductive member 154 is positioned at a channel portion of a thin film transistor where the first, second and third semiconductive members are formed on the gate insulating layer 140.

A plurality of ohmic contacts may be formed on each of the semiconductive members 151, 154, and 155, on the data line 171, and between source and drain electrodes, which are omitted in the drawing.

On each of the semiconductive members 151, 154, and 155 and the gate insulating layer 140, a plurality of data lines 171 including first and second source electrodes 173a and 173b, data conductors 171, 173c, 175a, 175b, and 175c including a first drain electrode 175a, a second drain electrode 175b, a third source electrode 173c, and a third drain electrode 175c are formed.

The first gate electrode 124a, the first source electrode 173a, and the first drain electrode 175a form a first thin film transistor Qa together with the semiconductive member 154, and a channel of the thin film transistor is formed at the semiconductive portion of member 154 between the first source electrode 173a and the first drain electrode 175a.

Similarly, the second gate electrode 124b, the second source electrode 173b, and the second drain electrode 175b form a second thin film transistor Qb together with the semiconductive member 154, and a channel of the thin film transistor is formed at the semiconductive portion of 154 between the second source electrode 173b and the second drain electrode 175b. The third gate electrode 124c, the third source electrode 173c, and the third drain electrode 175c form a third thin film transistor Qc together with the semiconductive member 154, and a channel of the thin film transistor is formed at the semiconductive portion of 154 between the third source electrode 173c and the third drain electrode 175c.

The data line 171 according to the present exemplary embodiment has a structure in which the width decreases in a thin film transistor formation region around an extension 175c′ of the third drain electrode 175c.

The structure is one for maintaining an interval from adjacent wiring and reducing signal interference, but does not necessarily need to be formed in this way.

A first passivation layer 180 is formed on the data conductors 171, 173c, 175a, 175b, and 175c and an exposed portion of the semiconductive member 154.

The first interlayer insulating layer 180a may include an inorganic insulating material such as a silicon nitride (SiNx), a silicon oxynitride (SiOxNy), and/or a silicon oxide (SiOx), or an organic insulating material.

A color filter 230 and a light blocking member 220 are formed on the first interlayer insulating layer 180a.

The light blocking member 220 has a lattice structure (e.g., defining a black matrix) having openings corresponding to a region where a pixel of an image is displayed, and is formed of a material through which light is not transmitted.

The color filter 230 is formed in the opening of the light blocking member 220.

The color filters 230 may display one of primary colors such as three primary colors of red, green, and blue.

However, the color filter 230 may also display one of cyan, magenta, yellow, and white colors or clear, not being limited to the three primary colors of red, green, and blue.

The color filter 230 may be formed of materials displaying different colors for each adjacent pixel.

The second interlayer insulating layer 180b is formed on the color filter 230 and the light blocking member 220.

The second interlayer insulating layer 180b may include an inorganic insulating material, such as a silicon nitride (SiNx) and/or a silicon oxide (SiOx), or an organic insulating material.

Contrary to the illustration in the cross-sectional view of FIG. 2, in case a step is generated due to a thickness difference of the color filter 230 and the light blocking member 220, a planarizing organic insulating material may be included to decrease or remove a step in the second interlayer insulating layer 180b.

A first contact hole 186a and a second contact hole 186b, which respectively expose the first drain electrode 175a and extensions 175b′ of the second drain electrode 175b, are formed in the color filter 230, the light blocking member 220, and the interlayer insulating layers 180a and 180b.

Further, a third contact hole 186c which exposes the protruding portion 134 of the storage voltage line 131 and the extension 175c′ of the third drain electrode 175c is formed in the color filter 230, the light blocking member 220, and the interlayer insulating layers 180a and 180b.

In the present exemplary embodiment, the light blocking member 220 and the color filter 230 also have the contact holes 186a, 186b, and 186c, but depending on the material of the light blocking member 220 and the color filter 230, etching of the contact holes may be difficult compared with etching of and thus patterning of the interlayer insulating layers 180a and 180b.

Thus, when etching the light blocking member 220 or the color filter 230, the light blocking member 220 or the color filter 230 may be removed in advance at the position where the contact holes 186a, 186b, and 186c are formed.

Meanwhile, depending on exemplary embodiments, the contact holes 186a, 186b, and 186c may be formed by changing a position of the light blocking member 220 and etching only the color filter 230 and the interlayer insulating layers 180a and 180b.

According to the exemplary embodiment, the first light blocking structure-forming layer 163 covers the contact hole 186.

As shown in FIG. 2, the first light blocking structure-forming layer 163 covers a drain contact hole 186 such that the contacted therethrough drain electrode 175 is not exposed.

In this instance, the first light blocking structure-forming layer 163 is an electrically conductive material that contacts the drain electrode 175 (where optionally, the first light blocking structure-forming layer 163 is also a light-passing material).

The first light blocking structure-forming layer 163 contacts the drain electrode 175 such that the electrically conductive material of the first light blocking structure-forming layer 163 can be electrically connected to the drain electrode 175.

The first light blocking structure-forming layer 163 may be further electrically connected to and/or a monolithically integral part of the pixel electrode 192 which will be described later.

According to the exemplary embodiment, the first light blocking structure-forming layer 163 may be integrally formed as a continuum of the pixel electrode 192.

Accordingly, the first light blocking structure-forming layer 163 may be made of the same material, such as indium tin oxide (ITO) or indium zinc oxide (IZO), as that of the pixel electrode 192.

The second light blocking structure-forming layer 165 is formed on the first light blocking structure-forming layer 163.

As shown in FIG. 2, the second light blocking structure-forming layer 165 is formed to overlap the first light blocking structure-forming layer 163.

In this instance, the second light blocking structure-forming layer 165 may contain an opaque and electrically conductive material. For example, it may comprise a metal such as titanium (Ti). The material of the second light blocking structure-forming layer 165 is selected to include one that is not damaged by a subsequent process step of selectively removing a sacrificial layer (300) where the selectively removal of the sacrificial layer may involve ashing and/or a wet etch.

According to the exemplary embodiment, the contact hole 186 formed at the interlayer insulating layers 180a and 180b is covered with the first and second light blocking structure-forming layers 163 and 165 which are respectively laminated with a plurality of layers.

Thus, light leakage into the thin film transistor forming region where TFT 154/173-175 is formed and the main light blocking member 220 is opened up for repair purposes may be prevented by adding on the higher up light blocking structure formed by the laminated combination of the first and second light blocking structure-forming layers 163 and 165.

Moreover, the first and second light blocking structure-forming layers 163 and 165 covering the contact hole 186 may not be damaged by an ashing process for forming the microcavity which will be described later.

In this instance, when the first and second light blocking structure-forming layers 163 and 165 according to the exemplary embodiment are respectively formed of indium tin oxide (or indium zinc oxide) and titanium, the drain electrode 175 may contain copper.

Herein, when the second light blocking structure-forming layer 165, the first light blocking structure-forming layer 163, and the drain electrode 175 are respectively made of titanium (Ti), indium zinc oxide (IZO), and copper and their thicknesses are respectively 125 nm, 460 nm, and 500 nm, the reflectance of the light blocking structure at least where the contact hole 186 is present may be reduced to about 9.21%.

Moreover, when the second light blocking structure-forming layer 165, the first light blocking structure-forming layer 163, and the drain electrode 175 are respectively made of titanium (Ti), indium zinc oxide (IZO), and copper and their thicknesses are respectively 125 nm, 460 nm, and 1000 nm, the reflectance of the light blocking structure at the contact hole 186 may be about 9.35%.

The pixel electrode 192 is formed on the second interlayer insulating layer 180b.

The pixel electrode 192 may be made of a transparent conductive material such as indium tin oxide (ITO) or indium zinc oxide (IZO).

The pixel electrode 192 may include a first sub-pixel electrode 192h and a second sub-pixel electrode 192l that are disposed adjacent to each other in a column direction, where the overall shape thereof is a quadrangle, and the first sub-pixel electrode 192h and the second sub-pixel electrode 192l include a cruciform stem part formed of a horizontal stem part and a vertical stem part intersecting the horizontal stem part.

Further, the first sub-pixel electrode 192h (upper or higher one) and the second sub-pixel electrode 192l (lower one) are each divided into four sub-regions by the horizontal stem part and the vertical stem part, and each sub-region includes a plurality of fine branch parts.

The fine branch parts of the first sub-pixel electrode 192h and the second sub-pixel electrode 192l form an angle of about 40 to 45 degrees with respect to the gate line 121 or the horizontal stem part.

Further, the fine branch parts of two adjacent sub-regions may be orthogonal to each other.

Further, the widths of the fine branch parts gradually become wider or an interval between the fine branch parts may be variable with radial distance away from the center.

The first sub-pixel electrode 192h and the second sub-pixel electrode 192l are physically and electrically and respectively connected to the first drain electrode 175a and the second drain electrode 175b, through respective contact holes 186a and 186b, and are respectively supplied with a data voltage from the first drain electrode 175a and the second drain electrode 175b of the shared transistor Q.

The description of the aforementioned thin film transistor Q and pixel electrode 192 is one example, and a structure of the thin film transistor and a design of the pixel electrode may be modified in various other ways to improve side visibility.

A lower alignment layer 11 is formed on the pixel electrode 192, and the lower alignment layer 11 may be a vertical liquid crystal alignment layer.

The lower alignment layer 11, which is a liquid crystal alignment layer, may be formed of any one among generally used materials such as polyamic acid, polysiloxane, or polyimide.

An upper alignment layer 21 is positioned at a portion facing the lower alignment layer 11, and, after the sacrificial layer is selectively removed, the resulting microcavity 305 is formed between the lower alignment layer 11 and the upper alignment layer 21.

A liquid crystal material including liquid crystal molecules 310 is injected into the formed microcavity 305, where the microcavity 305 is formed to include a liquid crystal injection hole 307.

The microcavity 305 may be formed along a column direction of the pixel electrode 192, that is, a vertical direction thereof.

In the present exemplary embodiment, an alignment material forming the alignment layers 11 and 21 and the liquid crystal material including the liquid crystal molecules 310 may be injected into the microcavity 305 by using capillary forces to cause ingestion of these fluids into the interior of the microcavity 305, where the alignment materials may be first hardened by heat and/or exposure to polymerizing radiation (e.g., UV light).

The microcavity 305 is divided in a vertical direction by a plurality of liquid crystal injection holes forming regions 307FP positioned at a portion overlapping the gate line 121, and may be formed in plural parallel and elongated forms with openings provided along the direction to which the gate line 121 is extended.

Each of the plurality of microcavities 305 may correspond to one pixel area or two or more pixel areas, and the pixel area may correspond to a region displaying an image. The common electrode 270 and the lower insulating layer 350 are positioned on the upper alignment layer 21.

The common electrode 270 receives the common voltage, and generates an electric field together with the pixel electrode 192 to which the data voltage is applied to determine a direction to which the interposed liquid crystal molecules 310 positioned within the microcavity 305 and thus between the two electrodes will be inclined.

The common electrode 270 forms a capacitor with the pixel electrode 192 to maintain the received voltage even after the thin film transistor (the pixel's switching element) is turned off.

The lower insulating layer 350 may be formed of a silicon nitride (SiNx) and/or a silicon oxide (SiO).

In the present exemplary embodiment, the common electrode 270 is described to be formed above the microcavity 305, but in another exemplary embodiment, the common electrode 270 may be formed to be disposed below the microcavity 305 so that liquid crystal can be driven according to a coplanar electrodes mode.

The roof layer 360 is positioned on the lower insulating layer 350.

The roof layer 360 plays a supporting role for forming the microcavity 305, which is a space created between the pixel electrode 192 and the common electrode 270 when the sacrificial material is sacrificed; for example by ashing.

The roof layer 360 may contain a photoresist or other organic materials.

An upper insulating layer 370 is positioned on the roof layer 360.

The upper insulating layer 370 may be in contact with a top surface of the roof layer 360.

The upper insulating layer 370 may be formed of a silicon nitride (SiNₓ) and/or a silicon oxide (SiOₓ).

A capping layer 390 (microcavity openings sealing layer) is positioned on the upper insulating layer 370.

The capping layer 390 contacts the top and lateral surfaces of the upper insulating layer 370, and the capping layer 390 covers the liquid crystal injection holes 307 of the respective microcavities 305 which are exposed by the corresponding liquid crystal injection holes forming region 307FP.

The capping layer 390 may be formed of a thermosetting resin, a silicon oxycarbide (SiOC), or graphene.

An overcoat layer (not shown) formed of an inorganic layer or an organic layer may be positioned on the capping layer 390.

The overcoat layer protects the liquid crystal molecules 310 injected into the microcavity 305 from external impacts, and serves to form a planarized surface at its top.

Referring to FIG. 3, a partition wall forming portion PWP is formed between the neighboring microcavities 305 in a horizontal direction.

The partition wall forming portion PWP may be formed along an extending direction of the data line 171, and may be covered by the roof layer 360.

The partition wall forming portion PWP is filled with the lower insulating layer 350, the common electrode 270, the upper insulating layer 370, and the roof layer 360, and these elements form the partition wall to divide or define respective ones of adjacent microcavities 305.

A polarizer (not shown) is positioned on the lower and upper insulating layers 350 and 370 of the substrate 110.

The polarizer may include a polarizing element for generating polarized light and a triacetyl cellulose (TAC) layer may be used for securing durability, and depending on an exemplary embodiment, determining directions of transmissive axes of an upper polarizer and a lower polarizer may be perpendicular or parallel to each other.

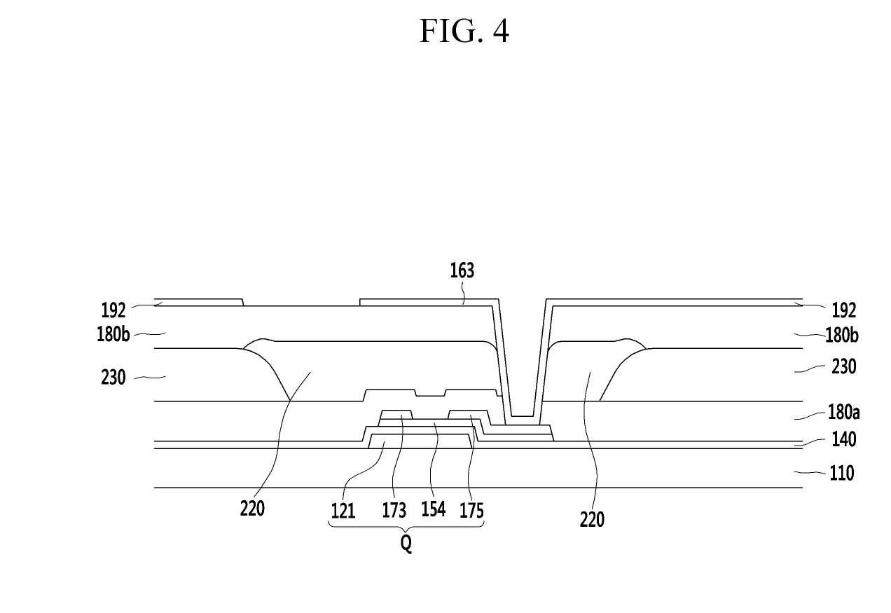

Hereinafter, the exemplary embodiment for manufacturing the liquid crystal display described above will be described with reference to FIGS. 4 to 12.

FIGS. 4 to 12 are drawings sequentially showing a manufacturing method of the liquid crystal display according to the exemplary embodiment.

Referring to FIG. 1 and FIG. 4, in order to form a generally known switching element on the substrate 110, the gate line 121 is formed to be extended in a horizontal direction, the gate insulating layer 140 is formed on the gate line 121, the semiconductive layers 151 and 154 are formed on the gate insulating layer 140, and the source electrode 173 and the drain electrode 175 are formed.

In this instance, the data line 171 connected with the source electrode 173 may be formed to be longitudinally extended in a vertical direction while crossing the gate line 121.

The first interlayer insulating layer 180a is formed on the data conductors 171, 173, and 175 including the source electrode 173, the drain electrode 175, and the data line 171, and the exposed portion of the semiconductive layer 154.

The color filter 230 is formed at a position corresponding to the pixel area on the first interlayer insulating layer 180a, and the light blocking member 220 is formed between the color filters 230.

The second interlayer insulating layer 180b covering the color filter 230 and the light blocking member 220 is formed on the color filter 230 and the light blocking member 220, and the second interlayer insulating layer 180b is formed to have the contact hole 186 which electrically and physically connects the pixel electrode 191 and the drain electrode 175.

Next, a pixel electrode layer is formed on the second interlayer insulating layer 180b.

In this instance, the pixel electrode layer covers the second interlayer insulating layer while filling in at least along the interior sidewalls of the contact hole 186.

For example, the pixel electrode layer may be formed by depositing a material including indium tin oxide (ITO) or indium zinc oxide (IZO) on the second interlayer insulating layer 180b.

As shown in FIG. 4, the first light blocking structure-forming layer 163 and the pixel electrode 192 may be simultaneously formed of a same material by accordingly patterning the pixel electrode layer. Testing of the TFT transistors (Q) may occur before or after the pixel electrode 192 of FIG. 4 is formed. As mentioned, repair of TFT's that are found to be defective may entail forming a repair hole through a corresponding portion of the light blocking member 220.

In this instance, the first light blocking structure-forming layer 163 contacts the drain electrode.

According to the exemplary embodiment, the first light blocking structure-forming layer 163 may be integrally formed with and as a continuum of the pixel electrode 192.

That is, the first light blocking structure-forming layer 163 is made of the same material as the pixel electrode 192.

For example, as described above, the first light blocking structure-forming layer 163 and the pixel electrode 192 may be made of indium tin oxide (ITO) or indium zinc oxide (IZO).

Next, the second light blocking structure-forming layer 165 is formed on the first light blocking structure-forming layer 163.

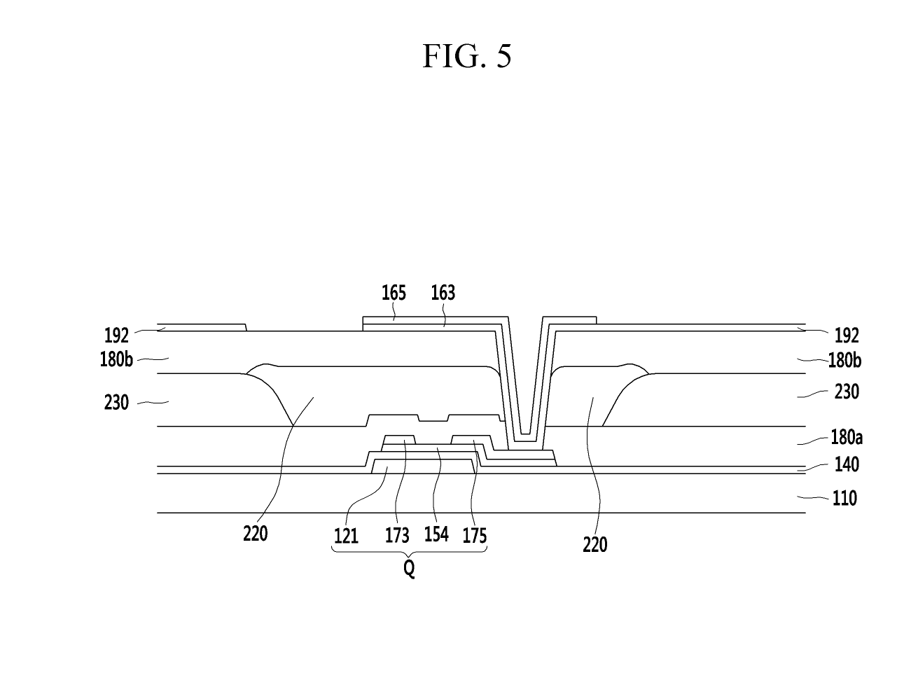

As shown in FIG. 5, the second light blocking structure-forming layer 165 is formed to overlap the first light blocking structure-forming layer 163.

Like the first light blocking structure-forming layer 163, the second light blocking structure-forming layer 165 may be formed by a conventional patterning method.

In this instance, the second light blocking structure-forming layer 165 may be made of an opaque metal such as titanium (Ti).

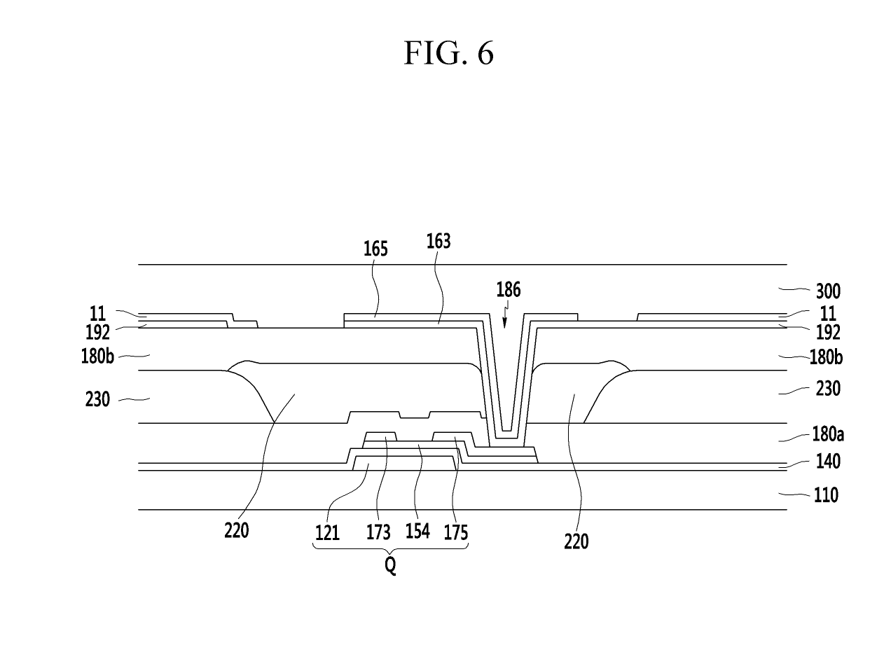

Then, as shown in FIG. 6, a sacrificial layer 300 is formed on the pixel electrode 192.

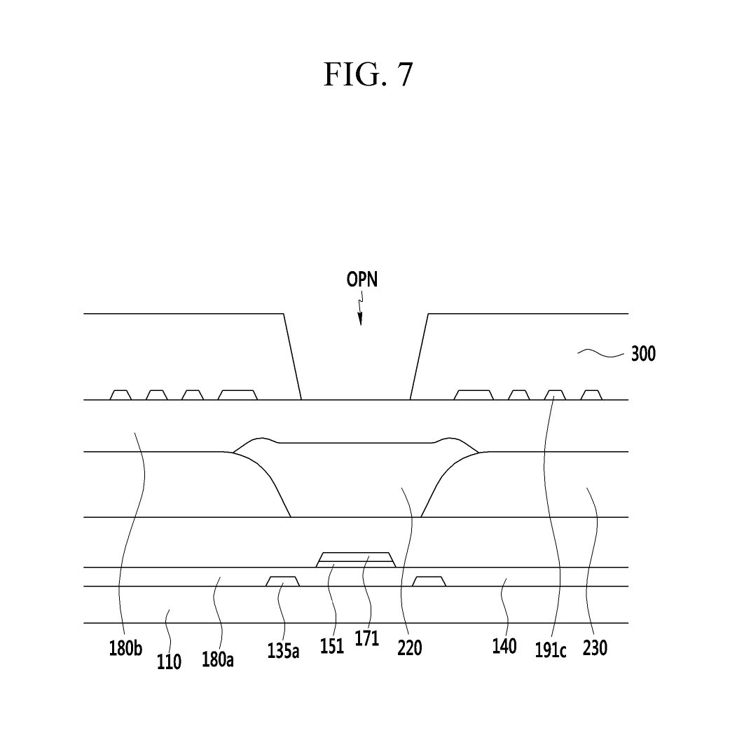

Referring to FIG. 7, the sacrificial layer 300 is formed with an open portion OPN along a direction parallel with the data line 171.

In subsequent processes, the open portion OPN may be filled in with the common electrode 270, the lower insulating layer 350, the roof layer 360, and the upper insulating layer 370 to form the partition wall forming portion PWP.

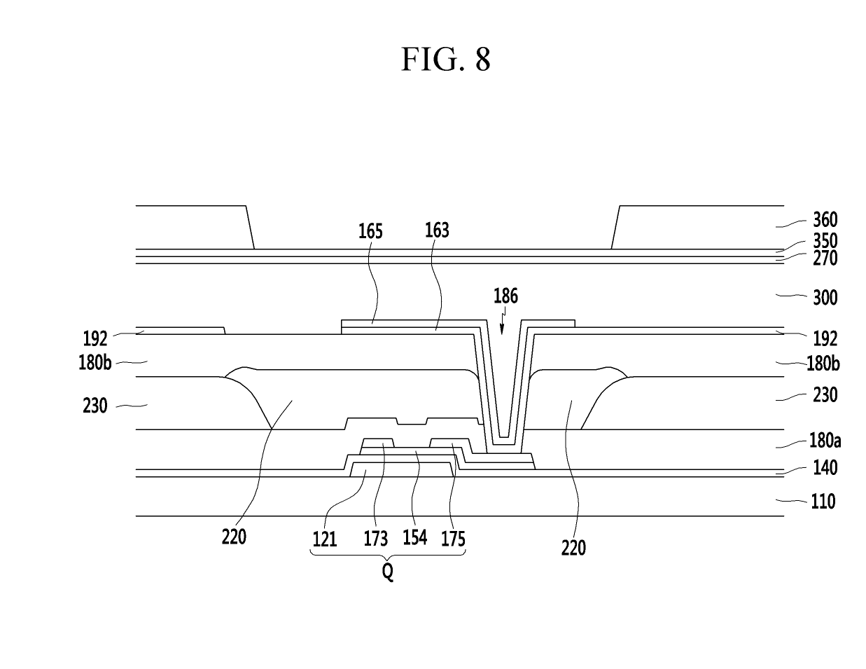

Referring to FIG. 8, the common electrode 270, the lower insulating layer 350, and the roof layer 360 are sequentially formed on the sacrificial layer 300.

The roof layer 360 may be removed by an exposure and development process in the region corresponding to the light blocking member 220 disposed between the pixel areas which are adjacent in the vertical direction. The roof layer 360 exposes the lower insulating layer 350 in the region corresponding to the light blocking member 220.

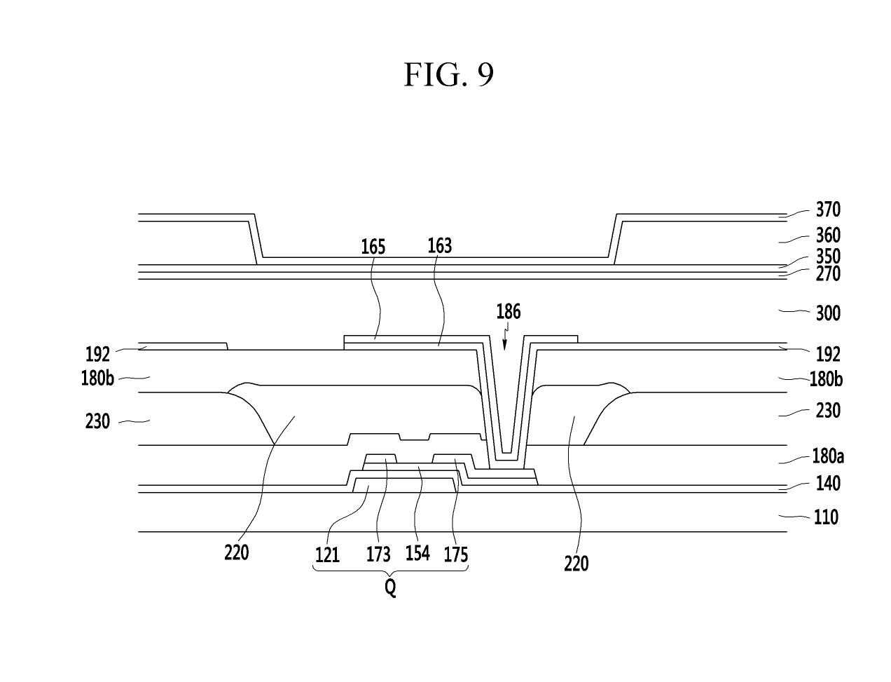

Referring to FIG. 9, the upper insulating layer 370 is formed to cover the exposed lower insulating layer 350 and the roof layer 360.

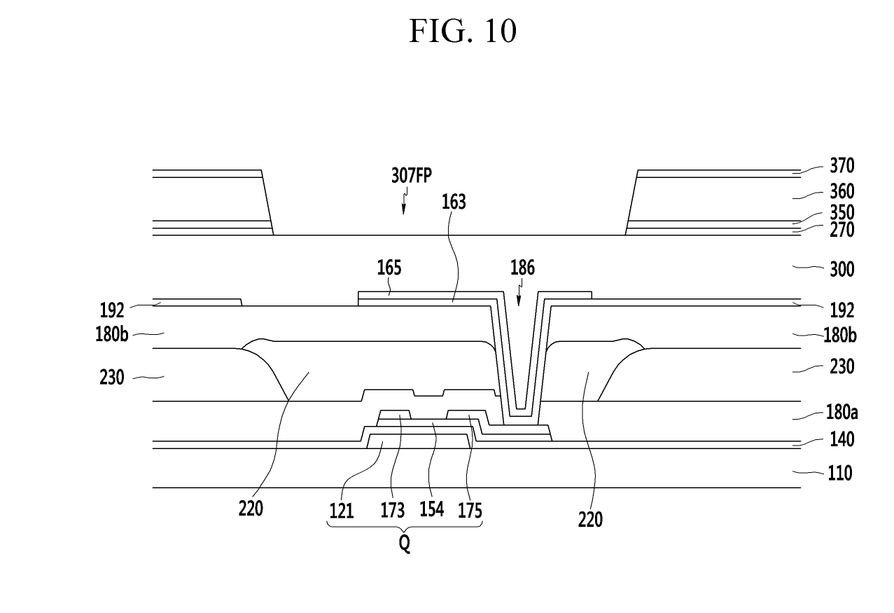

Referring to FIG. 10, the upper insulating layer 370, the lower insulating layer 350, and the common electrode 270 are dry etched by using an etching mask.

As a result, the upper insulating layer 370, the lower insulating layer 350, and the common electrode 270 are partially removed to form the liquid crystal injection holes forming region 307FP.

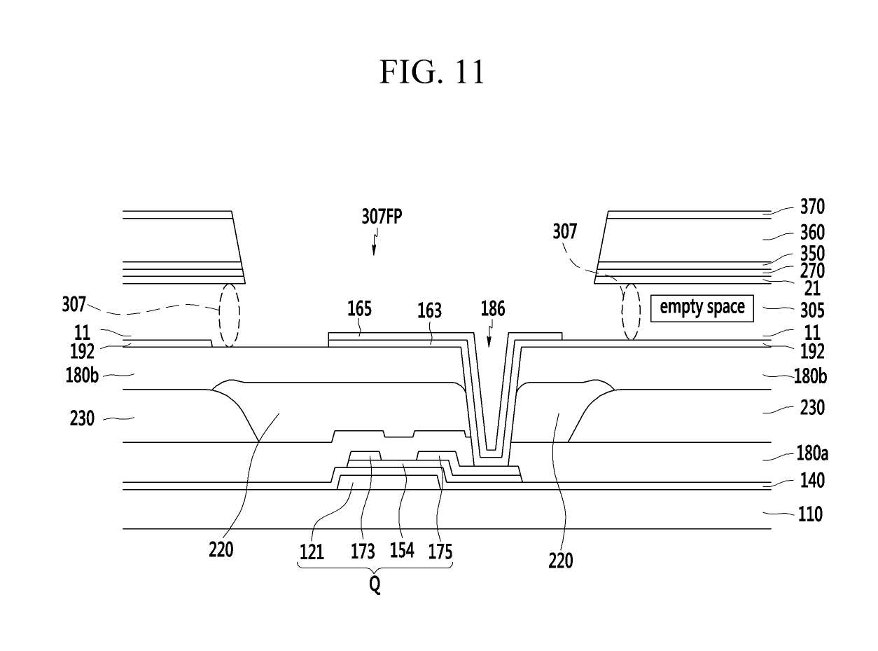

Referring to FIG. 11, the sacrificial layer 300 is selectively removed through the liquid crystal injection holes forming region 307FP for example by using an 02 ashing process or a selective wet etching method.

In this instance, the microcavity 305 having the liquid crystal injection hole 307 is formed.

The microcavity 305 is an empty space due to removal of the sacrificial layer 300.

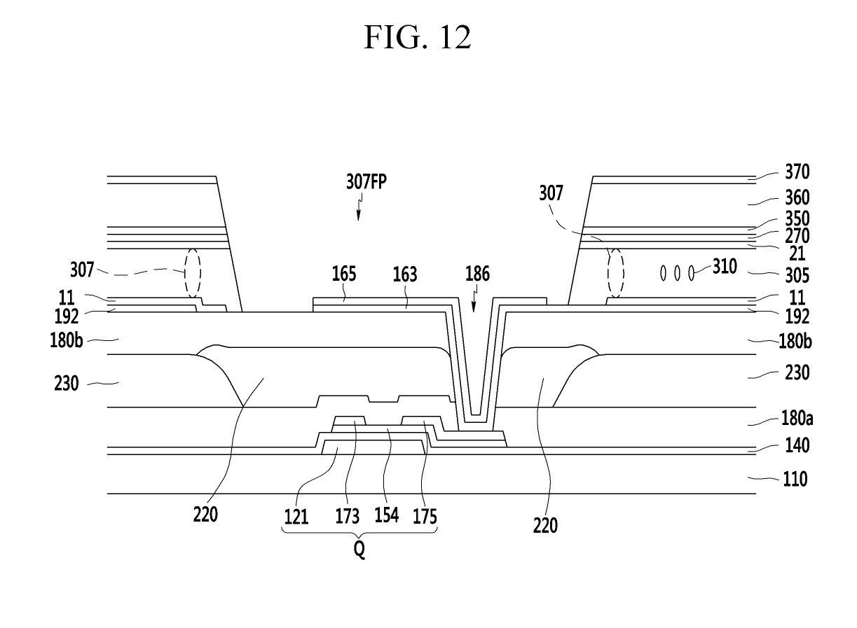

Referring to FIG. 12, the alignment material is first injected through the liquid crystal injection hole 307 to form the alignment layers 11 and 21 on the pixel electrode 192 and the common electrode 270.

In detail, the injected and initially fluidic alignment material including solids mixed with a solvent and injected as such into the liquid crystal injection hole 307, and then a bake process is performed to selectively volatilize and remove the solvent.

Next, through the liquid crystal injection hole 307, the liquid crystal material including the liquid crystal molecules 310 is injected into the microcavity 305 by using an inkjet method and the like and taking advantage of capillary ingestion effects to thereby form the liquid crystal display shown in FIG. 2.

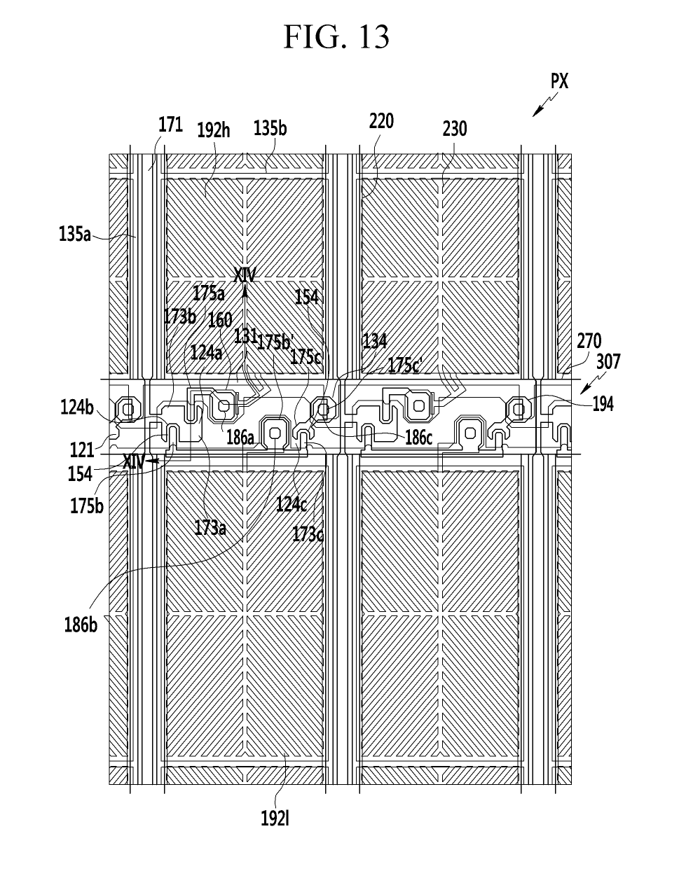

FIG. 13 is a top plan view of a liquid crystal display according to another exemplary embodiment.

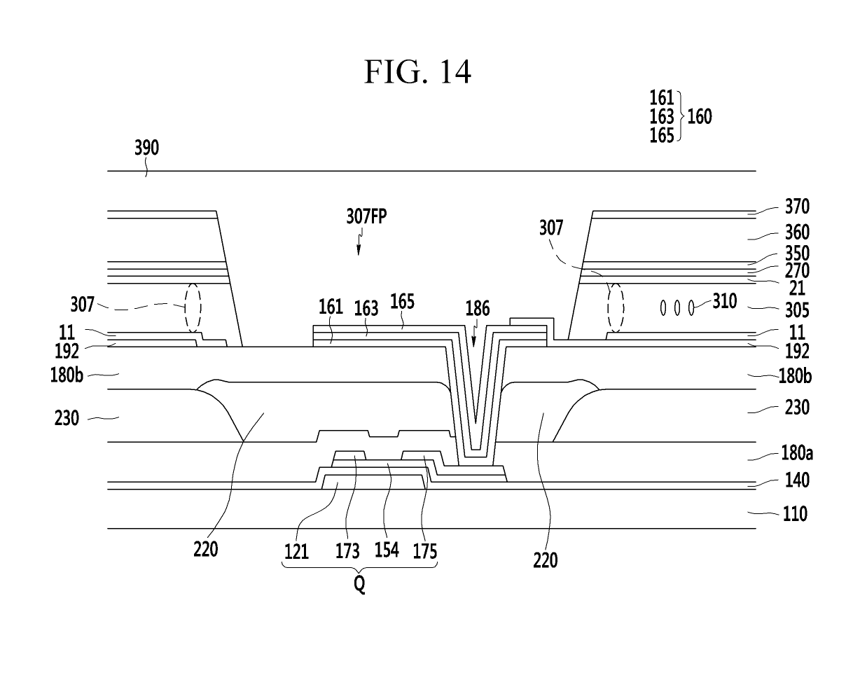

FIG. 14 is a cross-sectional view of FIG. 13, taken along the line XIV-XIV.

The exemplary embodiment shown in FIG. 13 and FIG. 14 is almost the same as the exemplary embodiment described in FIGS. 1 to 3.

However, in FIG. 14 it is shown that a multi-layered light blocking structure-forming member 160 having a plurality of layers covers the contact hole 186, and the pixel electrode 192 is positioned above and contacting the light blocking structure-forming member 160 to overlap and electrically connect with a portion thereof.

Except for the differences, the description of the exemplary embodiment of FIGS. 1 to 3 may be applied to the present exemplary embodiment.

A liquid crystal display according to the current exemplary embodiment is the same as the exemplary embodiment of FIGS. 1 to 3 except for the light blocking structure-forming member 160, which covers the contact hole 186 formed in the interlayer insulating layer 180b, and a structure of the pixel electrode 192.

Hereinafter, only the differences will be described.

Referring to FIG. 13 and FIG. 14, the light blocking structure-forming member 160 includes first to third light blocking structure-forming layers 163, 165, and 161 which cover the contact hole 186 formed through the interlayer insulating layer 180b. In more detail, the third light blocking structure-forming layer 161 covers the interior sidewalls of the contact hole 186.

As shown in FIG. 14, the third light blocking structure-forming layer 161 covers the contact hole 186 such that the drain electrode 175 is not exposed.

The third light blocking structure-forming layer 161 may be made of copper (Cu).

In this instance, the third light blocking structure-forming layer 161 contacts the drain electrode 175.

The third light blocking structure-forming layer 161 contacts the drain electrode 175 such that the third light blocking structure-forming layer 161 can be electrically connected to the drain electrode 175.

In the liquid crystal display according to the exemplary embodiment shown in FIGS. 1 to 3, it is the first light blocking structure-forming layer 163 which contacts the drain electrode 175, but in the different exemplary embodiment shown in FIG. 14, it is the third light blocking structure-forming layer 161 which contacts the drain electrode 175.

Further, the first light blocking structure-forming layer 163 is positioned on the third light blocking structure-forming layer 161.

The first light blocking structure-forming layer 163 is formed to overlap the third light blocking structure-forming layer 161.

In this instance, the first light blocking structure-forming layer 163 may be made of an electrically conductive light-passing material such as indium tin oxide (ITO) or indium zinc oxide (IZO).

In the liquid crystal display according to the exemplary embodiment shown in FIGS. 1 to 3, the first light blocking structure-forming layer 163 is integrally formed with the pixel electrode 192, but in the different exemplary embodiment shown in FIG. 14, the first light blocking structure-forming layer 163 is formed separately from (e.g., before) the formation of the pixel electrode 192.

Further, the second light blocking structure-forming layer 165 is formed on the first light blocking structure-forming layer 163.

As shown in FIG. 14, the second light blocking structure-forming layer 165 is formed to overlap the first light blocking structure-forming layer 163.

In this instance, the first light blocking structure-forming layer 165 may include an opaque metal such as titanium (Ti).

According to this other exemplary embodiment, the contact hole 186 formed in the interlayer insulating layers 180a and 180b is covered with the first to third light blocking structure-forming layers 163, 165, and 161.

Accordingly, light leakage of thin film transistor formation region where the light blocking member 220 is open for repair purposes may be prevented.

Moreover, the first to third light blocking structure-forming layers 163, 165, and 161 are not damaged by an ashing process used for forming the microcavity 305.

In this instance, in case the first to third light blocking structure-forming layers 163, 165, and 161 are respectively made of indium zinc oxide (or indium tin oxide) and titanium, the drain electrode 175 may be a triple layer which is sequentially laminated with molybdenum (Mo), aluminum (Al), and molybdenum (Mo).

Herein, when the first light blocking structure-forming layer 165, the first light blocking structure-forming layer 163, the third light blocking structure-forming layer 161, and the drain electrode 175 are respectively made of titanium (Ti), indium zinc oxide (IZO), copper (Cu), and Mo/Al/Mo and their respective thicknesses are 125 nm, 460 nm, and 500 nm, 1000 nm/3000 nm/500 nm, respectively, the reflectance of the light blocking structure-forming member in the region of the contact hole 186 may be about 9.36%.

Moreover, when the second light blocking structure-forming layer 165, the first light blocking structure-forming layer 163, the third light blocking structure-forming layer 161, and the drain electrode 175 are respectively made of titanium (Ti), indium zinc oxide (IZO), and copper (Cu), and Mo/Al/Mo and their respective thicknesses are 125 nm, 460 nm, and 1000 nm, 1000 nm/3000 nm/500 nm, respectively, the reflectance of the light blocking structure-forming member to the contact hole 186 may be about 9.35%.

Meanwhile, the pixel electrode 192 may be afterwards electrically connected to the top of the light blocking structure-forming member 160.

According to this other exemplary embodiment, the pixel electrode 192 therefore contacts the light blocking structure-forming member 160 rather than being a monolithically integral extension thereof.

In more detail, the pixel electrode 192 partially contacts the second light blocking structure-forming layer 165.

Except for the differences described above, the description of the exemplary embodiment of FIGS. 1 to 3 may be applied to the present exemplary embodiment.

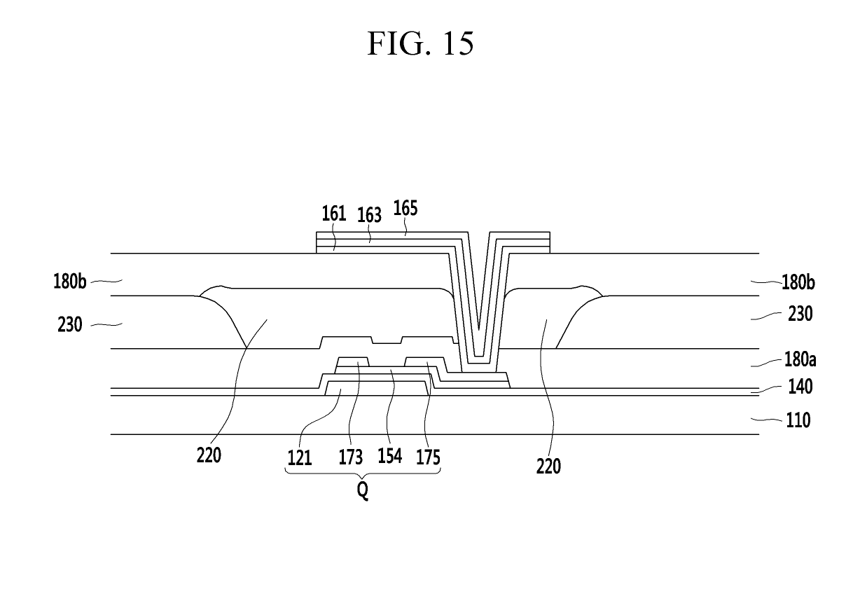

FIGS. 15 to 17 are drawings sequentially showing the manufacturing method of the liquid crystal display according to yet another exemplary embodiment.

The manufacturing method of the liquid crystal display according to the current exemplary embodiment partially differs from the manufacturing method of the crystal display according to the exemplary embodiment shown FIGS. 4 to 12 with respect to forming the light blocking structure-forming member 160 and the pixel electrode 192.

Except for the differences, the description of the exemplary embodiment of FIGS. 4 to 12 may be applied to the present exemplary embodiment.

Referring to FIG. 15, in order to form a generally known switching element on a substrate 110, the gate line 121 is formed to be extended in a horizontal direction, the gate insulating layer 140 is formed on the gate line 121, the semiconductive layers 151 and 154 are formed on the gate insulating layer 140, and the source electrode 173 and the drain electrode 175 are formed.

In this instance, the data line 171 connected with the source electrode 173 may be formed to be extended in a vertical direction while crossing the gate line 121.

The first interlayer insulating layer 180a is formed on the data conductors 171, 173, and 175 including the source electrode 173, the drain electrode 175, and the data line 171, and the exposed portion of the semiconductive layer 154.

The color filter 230 is formed at a position corresponding to the pixel area on the first interlayer insulating layer 180a, and the light blocking member 220 is formed between the color filters 230.

The second interlayer insulating layer 180b covering the color filter 230 and the light blocking member 220 is formed on the color filter 230 and the light blocking member 220, and the second interlayer insulating layer 180b is formed to have the contact hole 186 which electrically and physically connects the pixel electrode 191 and the drain electrode 175.

Next, as shown in FIG. 15, the third light blocking structure-forming layer 161, the first light blocking structure-forming layer 163, and the second light blocking structure-forming layer 165 are sequentially laminated to cover the contact hole 186.

The third light blocking structure-forming layer 161 contacts the drain electrode 175.

In this instance, the first to third light blocking structure-forming layers 163, 165, and 161 may respectively include indium zinc oxide (or indium tin oxide), titanium (Ti), and copper (Cu).

Next, the pixel electrode 192 is formed on the second interlayer insulating layer 180b.

In more detail, the pixel electrode layer is formed on the second interlayer insulating layer 180b and the second light blocking structure-forming layer 165.

In this instance, the pixel electrode layer may be formed by depositing a material including indium tin oxide (ITO) or indium zinc oxide (IZO) on the second interlayer insulating layer 180b.

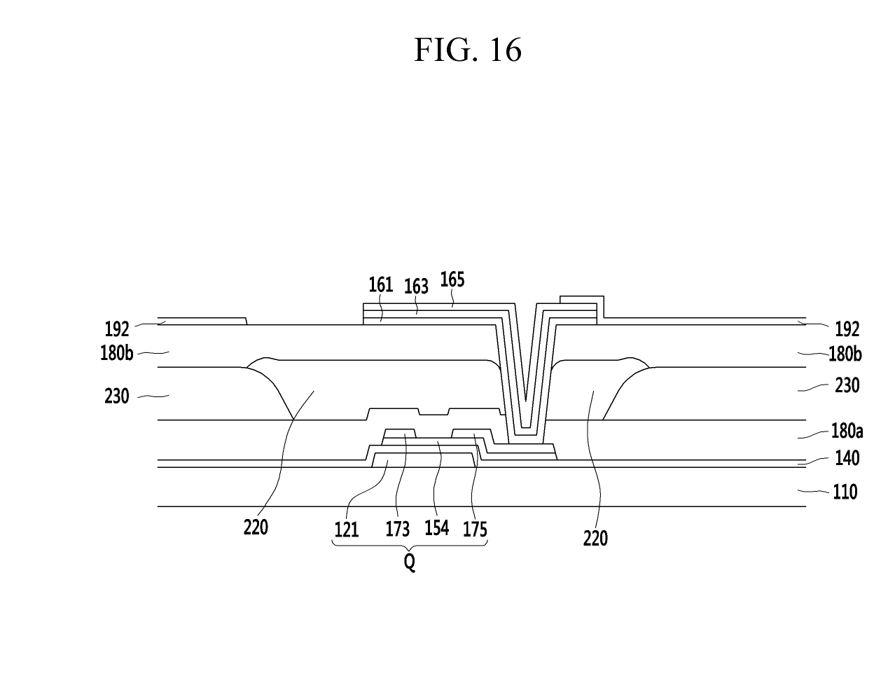

As shown in FIG. 16, the pixel electrode 192 may be formed by patterning the pixel electrode layer.

That is, the pixel electrode 192 is formed to partially overlap and contact the second light blocking structure-forming layer 165.

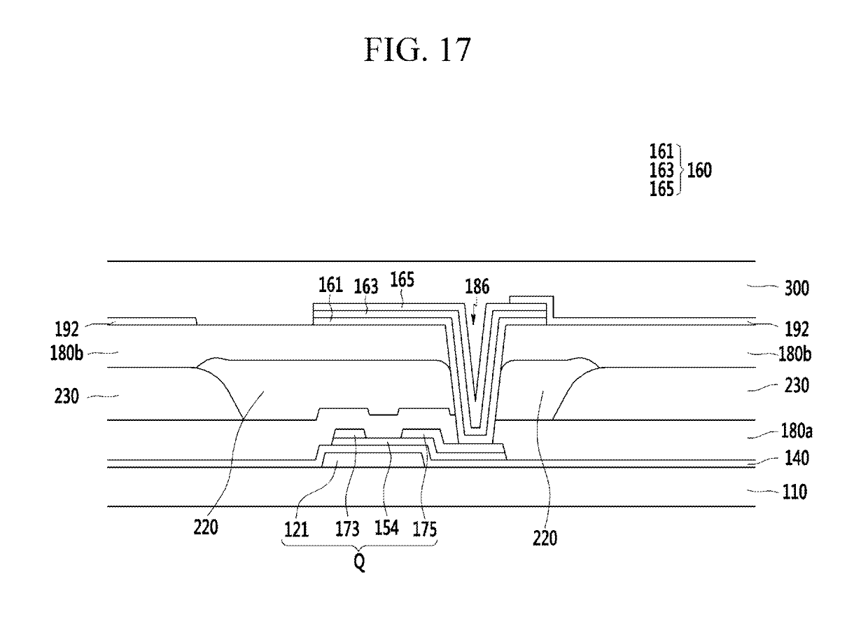

Then, as shown in FIG. 17, the sacrificial layer 300 is formed on the pixel electrode 192.

The subsequent processes for forming the microcavities are the same as the processes described above in FIGS. 8 to 12.

Accordingly, a detailed description thereof will be omitted.

The liquid crystal display and the manufacturing method thereof according to one exemplary embodiment prevents the light blocking structure-forming layer from being damaged due to an ashing process for forming the microcavity by covering the thin film transistor forming region, where the light blocking member is exposed, with the light blocking structure-forming member having the plurality of layers.

While this disclosure of invention has been described in connection with what is presently considered to be practical exemplary embodiments, it is to be understood that the teachings are not limited to the disclosed embodiments, but, on the contrary, are intended to cover various modifications and equivalent arrangements included within the spirit and scope of the present disclosure.

What is claimed is:

1. A liquid crystal display comprising:
a substrate;
a thin film transistor including a semiconductive layer formed on the substrate and source and drain electrodes which are formed on the semiconductive layer;
an interlayer insulating layer formed on the thin film transistor and formed with a contact hole exposing the drain electrode;
a first light blocking structure-forming layer covering the contact hole, the first light blocking structure-forming layer being electrically conductive and being electrically coupled to the drain electrode;
a second light blocking structure-forming layer formed on the first light blocking structure-forming layer;
a pixel electrode formed on the interlayer insulating layer; and
a common electrode disposed on the substrate and spaced apart from and facing the pixel electrode,
wherein the substrate has defined therein, a microcavity having a liquid crystal injection hole, the microcavity being formed between the pixel electrode and the common electrode, and the microcavity containing a liquid crystal portion formed of liquid crystal molecules.

2. The liquid crystal display of claim 1, wherein
the first light blocking structure-forming layer contacts the drain electrode.

3. The liquid crystal display of claim 1, wherein
the second light blocking structure-forming layer overlaps the first light blocking structure-forming layer.

4. The liquid crystal display of claim 1, wherein
the first light blocking structure-forming layer is connected to the pixel electrode.

5. The liquid crystal display of claim 4, wherein
the first light blocking structure-forming layer is integrally formed as a continuum of the pixel electrode.

6. The liquid crystal display of claim 5, wherein
the drain electrode contains copper (Cu).

7. The liquid crystal display of claim 1, wherein
the first light blocking structure-forming layer is a light-passing electrically conductive layer which, for example, contains indium tin oxide (ITO) or indium zinc oxide (IZO).

8. The liquid crystal display of claim 1, wherein
the second light blocking structure-forming layer contains an opaque metal such as for example, titanium (Ti).

9. The liquid crystal display of claim 1, further comprising
a light blocking member, separate from the first and second light blocking structure-forming layers, and disposed between the thin film transistor and the interlayer insulating layer,
wherein the light blocking member is formed with an opening positioned over the contact hole that exposes the drain electrode so that optional repair of the thin film transistor or a contact thereto may take place through the opening formed in the light blocking member.

10. The liquid crystal display of claim 9, further comprising
a lower insulating layer disposed on the common electrode.

11. The liquid crystal display of claim 10, further comprising
a roof layer disposed on the lower insulating layer.

12. The liquid crystal display of claim 11, further comprising
a capping layer disposed on the roof layer and covering the liquid crystal injection hole.

13. The liquid crystal display of claim 12, wherein
the first recited microcavity is one of plural microcavities integrally defined within the substrate, the plural microcavities corresponding to respective pixel regions of the liquid crystal display, and
the substrate further has defined as a part thereof, a liquid crystal injection holes forming region that is formed between the plurality of regions and that includes at least one liquid crystal injection hole of a respective at least one of the plural microcavities, and the capping layer covers the liquid crystal injection holes forming region.

14. The liquid crystal display of claim 13, wherein
the liquid crystal injection holes forming region is formed in a direction parallel with a gate line connected to the thin film transistor.

15. The liquid crystal display of claim 1, further comprising
a third light blocking structure-forming layer disposed under the first light blocking structure-forming layer contacting the drain electrode.

16. The liquid crystal display of claim 15, wherein
the pixel electrode is connected to the second light blocking structure-forming layer.

17. The liquid crystal display of claim 15, wherein
the pixel electrode overlaps the second light blocking structure-forming layer.

18. The liquid crystal display of claim 15, wherein
the first to third light blocking structure-forming layers are disposed so as to overlap each other.

19. The liquid crystal display of claim 15, wherein
the drain electrode has a triple layer structure formed as a sequential lamination of molybdenum (Mo), aluminum (Al), and molybdenum (Mo).

20. The liquid crystal display of claim 15, wherein
the third light blocking structure-forming layer contains copper (Cu).

21. A manufacturing method of the liquid crystal display comprising:
forming a thin film transistor on a substrate;
forming an interlayer insulating layer on the thin film transistor;
forming a contact hole at the interlayer insulating layer to expose a drain electrode of the thin film transistor;
forming a pixel electrode layer on the interlayer insulating layer;
forming a first light blocking structure-forming layer and a pixel electrode by patterning the pixel electrode layer;
forming a second light blocking structure-forming layer on the first light blocking structure-forming layer;
forming a sacrificial layer on the second light blocking structure-forming layer and the pixel electrode;
forming a common electrode on the sacrificial layer;
forming a roof layer on the common layer;
forming a liquid crystal injection holes forming region by patterning the common electrode and the roof layer; and
forming one or more microcavities that are accessible by way of at least one liquid crystal injection hole, the forming of the one or more microcavities including selectively removing the sacrificial layer.

22. The method of claim 21, wherein
the first light blocking structure-forming layer is formed to contact the drain electrode while covering the contact hole.

23. The method of claim 21, wherein
the first light blocking structure-forming layer is integrally formed as a continuum of the pixel electrode.

24. The method of claim 21, further comprising
forming a light blocking member disposed between the thin film transistor and the interlayer insulation member,
wherein the light blocking member is formed to have an opening corresponding to the contact hole exposing the drain electrode.

25. A manufacturing method of the liquid crystal display, comprising:
forming a thin film transistor on a substrate;
forming an interlayer insulating layer on the thin film transistor;
forming a contact hole at the interlayer insulating layer to expose a drain electrode of the thin film transistor;
forming a third light blocking structure-forming layer on the interlayer insulating layer to cover the contact hole;
forming a first light blocking structure-forming layer on the third light blocking structure-forming layer in order to overlap the third light blocking structure-forming layer;
forming a second light blocking structure-forming layer on the first light blocking structure-forming layer in order to overlap the first light blocking structure-forming layer;
forming a pixel electrode on the interlayer insulating layer;
forming a sacrificial layer on the second light blocking structure-forming layer and the pixel electrode;
forming a common electrode on the sacrificial layer;
forming a roof layer on the common electrode;
forming a liquid crystal injection holes forming region by patterning the common electrode and the roof layer; and
forming one or more microcavities that are accessible by way of at least one liquid crystal injection hole, the forming of the one or more microcavities including selectively removing the sacrificial layer.

26. The method of claim 25, wherein
forming a pixel electrode on the interlayer insulating layer includes forming a pixel electrode layer on the interlayer insulating layer and the second light blocking structure-forming layer, and forming the pixel electrode by patterning the pixel electrode layer.

27. The method of claim 25, wherein
the pixel electrode is formed to partially overlap the second light blocking structure-forming layer.

28. The method of claim 25, wherein
the pixel electrode is connected to the second light blocking structure-forming layer.

29. The method of claim 25, further comprising
forming a light blocking member disposed between the thin film transistor and the interlayer insulating layer,
wherein the light blocking member is formed to have an opening corresponding to the contact hole exposing the drain electrode.
